(19) United States
(12) Patent Application Publication
(10) Pub. No.: US 2007/0121966 A1
(43) Pub. Date: May 31, 2007

(54) Volume normalization device

(75) Inventors: Daniel Plastina, Redmond, WA (US); James David Johnston, Redmond, WA (US); Sergey Smirnov, Redmond, WA (US)

Correspondence Address: SHOOK, HARDY & BACON L.L.P.;(c/o MICROSOFT CORPORATION), INTELLECTUAL PROPERTY DEPARTMENT, 2555 GRAND BOULEVARD, KANSAS CITY, MO, 64108-2613, US

(73) Assignee: Microsoft Corporation, Redmond, WA (US)

(21) Appl. No.: 11/289,398

(22) Filed: Nov. 30, 2005

(51) Int. Cl. H03G 3/00

(52) U.S. Cl. 381/104; 381/107

(57) ABSTRACT

A method and system are provided for equalizing the loudness of an audio source. Initially, the perceptual loudness level of an audio signal is measured from one or more audio sources. Next, the loudness level of the audio signal is adjusted using the perceptual loudness level. Thereafter, the audio signal corresponding to the music selections is reproduced such that the perceived loudness to a listener is the same entirely throughout a music track corresponding to the music selections.

### CROSS-REFERENCE TO RELATED APPLICATIONS

None.

### STATEMENT REGARDING FEDERALLY SPONSORED RESEARCH OR DEVELOPMENT

None.

### BACKGROUND

The boom in digital electronics has increased the accessibility of digital audio products such as audio CDs and MP3 music files. Given the accessibility of audio products, users can now listen to a wide assortment of music. Because users have greater access to a wide range of music, users have become more sophisticated in their listening preference. As such, users are highly sensitive to their music quality. In particular, the users are highly sensitive to their sound quality. One particular concern for a user is the changing of a volume level while listening to a song.

Conventional audio players attempt to solve the problem by using various intensity metrics to guide level control. Because these audio players use intensity methods for measuring the signal, these audio players inaccurately normalize due to the failure of the audio players to consider perceptual issues. In other words, because these players use an analytic power or amplitude measurement, although sometimes frequency weighted or band limited, substantial perceptual error still exists.

Accordingly, a volume normalization device should allow for perceptual volume normalization while reducing distortion or errors in the resulting sound as perceived by a listener.

### BRIEF SUMMARY

In an embodiment, the volume normalization device should measure perceptual loudness of a signal rather than intensity. The volume normalization device should use a psychoacoustic derived approximate loudness measure to determine loudness. The volume normalization device should also equalize the loudness of different audio sources via an audio compressor.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

The present invention is described in detail below with reference to the attached drawings figures, wherein:

FIG. 1 is a block diagram illustrating details of a system in accordance with an embodiment of the invention;

FIG. 2 is block diagram illustrating a loudness control module for automatic acoustic calibration in accordance with an embodiment of the invention;

FIG. 3 is flow chart illustrating a loudness equalization method in accordance with an embodiment of the invention;

FIG. 4 is a flow chart illustrating an audio play list compilation method in accordance with an embodiment of the invention.

### DETAILED DESCRIPTION

Embodiments of the present invention are directed to a method and system for equalizing the loudness of audio sources. In an embodiment, the invention measures the perceptual loudness level of an audio signal from one or more audio sources. In such an embodiment, the invention also adjusts, dynamically or statically, the loudness level of the audio signal using the perceptual loudness level. The audio signal corresponding to the music selections can be reproduced such that the perceived loudness to a listener is normalized throughout an entire music track or among all the music tracks that corresponds to a music selection stored on an audio source.

Intensity generally includes a measurement of voltage, current, sound pressure level, or other measurement characteristics that calculates the actual power or amplitude of the signal. Intensity generally does not include perceptual issues. Loudness generally includes the internal perception of an audio signal, in terms of how loud it is actually perceived. Loudness, especially across audio with different frequency content and bandwidth, generally does not track intensity very well.

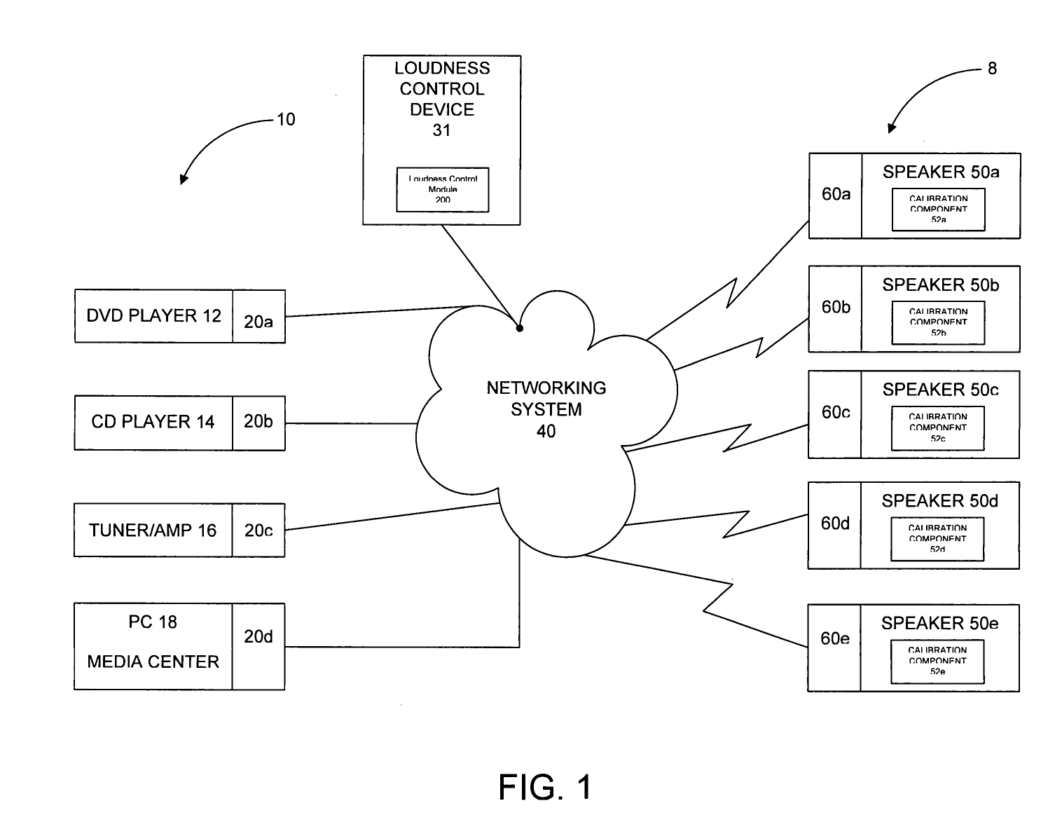

FIG. 1 shows an exemplary system embodiment of the invention. Various audio or audio-visual (A/V) source devices 10 may be connected via an IP networking system 40 to a set of rendering devices 8. In the displayed environment, the audio source devices 10 include a DVD player 12, a CD Player 14, a tuner 16, and a personal computer (PC) Media Center 18. Other types of source devices may also be included. The networking system 40 may include any of multiple types of networks such as a Local Area Network (LAN), Wide Area Network (WAN) or the Internet. Internet Protocol (IP) networks may include IEEE 802.11(a,b,g), 10/100Base-T, and HPNA. The networking system 40 may further include interconnected components such as a DSL modem, switches, routers, coupling devices, etc. Other configurations of the networking system 40 may also include receivers, portable devices, cell phones, etc. The rendering devices 8 may include multiple speakers 50a-50e. A loudness control device 31 performs the system loudness equalizing functions using a loudness control module 200.

In the embodiment of the system shown in FIG. 1, the loudness control device 31 includes a loudness control module 200. In additional embodiments, the loudness control module 200 could optionally be located in the Media Center PC 18 or other location. The loudness control module 200 interacts with each of a plurality of loudness control components 52a-52e attached to the speakers 50a-50e.

Loudness Control Components

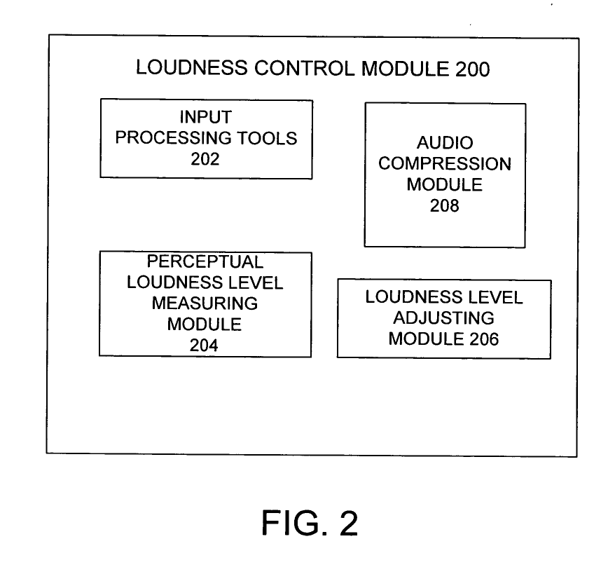

FIG. 2 illustrates a loudness control module 200 for calibrating the system of FIG. 1 from the loudness control device 31. The loudness control module 200 may be incorporated in a memory of the loudness control device 31 such as the RAM or other memory device. The loudness control module 200 may include input processing tools 202, a perceptual loudness level-measuring module 204, a loudness level adjusting module 206, and an audio compression module 208.

In an embodiment, the input processing tools 202 receive an audio signal generated from one or more audio sources. The audio sources can have multiple music selections with multiple musical tracks associated with each music selection. The perceptual loudness level-measuring module 204 calculates the perceptual loudness level that corresponds to the audio signal. The loudness level-adjusting module 206 adjusts the loudness level of the audio signal based on the measured perceptual loudness level. As a result, the audio compression module 208 further processes the audio signal. After the audio signal is compressed, the audio signal is reproduced corresponding to a music selection at a desired perceived loudness level to a listener.

Techniques for performing these functions are further described below in conjunction with the description of the audio play list compilation application.

Loudness Equalization Method

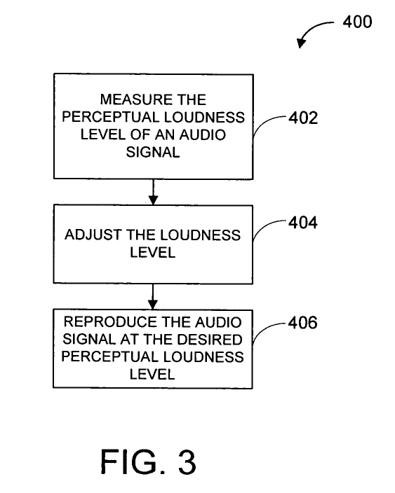

FIG. 3 is a flow chart for equalizing the loudness of an audio source performed with a loudness control module 200 and the loudness control components 52a-52e. At a step 402, the perceptual loudness level of an audio signal generated from multiple audio sources is measured. The audio sources can have multiple music selections. The audio sources can include audio CDs, and MP3 files. The music selections can have multiple music tracks.

At a step 404, the perceptual loudness level of the audio signal is adjusted using the perceptual loudness level. Preferably, the perceptual loudness level is a target loudness level determined by a listener.

At a step 406, the audio signal is reproduced corresponding to at least one music selection at a desired perceptual loudness level. In an embodiment, the variation of the perceived loudness of the audio signal to a listener is substantially reduced throughout a track corresponding to the music selections. In another embodiment, the peak perceived loudness of the audio signal to a listener is the same among all the tracks corresponding to the music selections.

Furthermore, according to an embodiment, additional steps for measuring the perceptual loudness level may include generating a Hann window; taking a Fast Fourier Transform (FFT) of a half-overlapped, windowed signal, mapping the power spectrum to the bark spectrum; spreading the energy in the bark spectrum; calculating the partial perceptual loudness values corresponding to the audio signal; aggregating the partial perceptual loudness values corresponding to the audio signal; and comparing the aggregated partial perceptual loudness values to the target loudness level. Additionally, other psychometrically determined scales may be used such as “Equivalent Rectangular Bandwidth”.

In another embodiment, additional steps for measuring the perceptual loudness level may include receiving a music track having one or more portions; selecting a target loudness corresponding to the music track; and assigning the target loudness to each portion. In such an embodiment, the step for adjusting the perceptual loudness level may also include normalizing each portion by a normalization factor to reach the target loudness. In an alternate embodiment, the step for adjusting the perceptual loudness level may also include normalizing the loudness of the music track using a normalization factor to reach the target loudness. Preferably, the normalization factor can be determined based on either peak or average loudness corresponding to each portion. Alternatively, the normalization factor can be determined by a maximum loudness corresponding to the music track.

In still another embodiment, the step for adjusting the loudness level of an audio signal may include determining the appropriate gain level using the comparison results of the aggregated partial perceptual loudness values with the target loudness level for inputting the audio signal into an audio compressor.

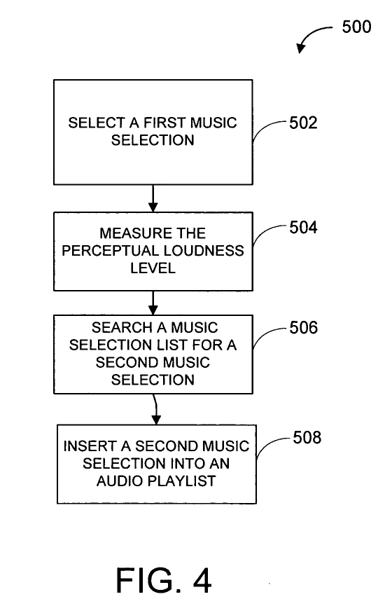

FIG. 4 is an exemplary embodiment showing a flow chart 500 for compiling an audio play list with similar loudness levels using the loudness control module 200 and the loudness control components 52a-52e. At a step 502, a first music selection is selected from multiple audio sources. At a step 504, the perceptual loudness level of an audio signal is measured corresponding to the first music selection. At a step 506, a second music selection is identified using the measured perceptual loudness level of the first music selection. At a step 508, a second music selection is inserted into an audio play list. Preferably, the second music selection has a perceptual loudness level that is similar to the measured perceptual loudness level of the first music selection.

In another embodiment, additional steps for compiling an audio play list may include identifying a second music selection if the second music selection has a perceptual loudness level that is equal to the measured perceptual loudness of the first music selection; rejecting the second music selection if the second music selection has a perceptual loudness level that is not equal to the measured perceptual loudness of the first music selection; and detecting the energy level corresponding to the music selection.

In some instances the aforementioned steps could be performed in an order other than that specified above. The description is not intended to be limiting with respect to the order of the steps.

One Pass and Two Pass Applications

In an embodiment, the invention provides a method for equalizing the loudness of an audio source. The method includes measuring the perceptual loudness level of an audio signal corresponding to a music track from an audio source, adjusting the perceptual loudness level of the audio signal; and reproducing the audio signal at the adjusted loudness level to a listener.

Preferably, the audio source includes audio CDs, WMA files, MP3 files, and other forms of audio storage or streaming. The audio source can be played in any device that is capable of playing audio content. Once the audio source is played in audio source playing device, an audio signal is generated corresponding to a music track stored on the audio source. The audio signal is inputted into the loudness control device 31 via input processing tools 202. At the loudness control device 31, the perceptual loudness level of the audio signal is measured.

For measuring the perceptual loudness level of an audio signal, a series of operations take place by the loudness control module 200. The perceptual loudness level-measuring module 204 uses a Hann window. A Hann window (H(n)) can be defined for these purposes as being H(n)=0.5−0.5*cosine(2*pi(n+0.5)/N), where N is the length of the window. Alternatively, other analysis windows may be used such as Blackmun window, Kaiser window, Hamming window, or any analysis window known in the art. In one embodiment, the Hann window is applied to the audio data using a ½ overlap (i.e. calculate a new loudness value every N/2 samples for an N sample window). The length may include 512 samples for most normal audio sampling rates. For example, N can be determined by dividing the sample rate by 100, and then taking that result and finding the smallest power of two that is larger than that result. Next, the data is modified by a fast Fourier Transform, and the power spectrum is calculated. Thereafter, the energy across each bark is summed. This allows the energy to spread upwards between barks, and the values from the same bark of multiple channels (if present) to sum together. Preferably, the value is compressed with a power law of 1/3.5 in order to provide partial loudness values, and then the partial loudness values are summed to yield the loudness of the given block of data centered in the Hann window. Alternatively, other mathematical operations can be used to generate the loudness. After the Hann window is generated, a bark scale mapping is performed.

In one embodiment, the bark scale mapping may be achieved by calculating the energy at each point in the positive frequency piece of the above-mentioned FFT, and then summing the energies across each bark, calculating the energy Bark by Bark. Using this calculation, the energy is calculated in each bark. Next, an elementary spreading function is generated by convolving a simple filter with the bark spectrum. Additionally, this embodiment avoids a full convolution of the FFT spectra. Alternatively, other mathematical operations can be used to create a bark scale mapping. Additionally, while the use of the internationally standardized Bark scale is used here, it is possible to use an “ERB” (equivalent rectangular bandwidth) or other scales that correspond to the filter configuration of the ear and obtain similar, and useful results.

For calculating the partial loudness values, the energy values are raised to the proper fractional power and the total loudness is summed across all the barks. After the partial loudness values, the aggregated partial perceptual loudness values are compared to the desired target loudness level. Thereafter, the appropriate gain level is determined using the comparison results of the aggregated partial perceptual loudness values with the target loudness level. In one embodiment, appropriate gain level is determined by calculating the ratio of the desired loudness to the actual loudness, raising the results of ratio calculation to the inverse power/2, and providing those results as the desired gain input to the audio compression module 208. Alternatively, other mathematical operations can be used to calculate the appropriate gain level.

The loudness level-adjusting module 206 adjusts the loudness level of the audio signal based on results of the perceptual loudness level-measuring module 204. In one embodiment, the loudness adjustment to the audio signal may be a volume normalization of a single music track corresponding to a music selection. In other words, reproducing the audio signal, or playing a musical track, can have the same volume level entirely throughout the track. In such an embodiment, the music track is divided into portions. The portions are scanned separately to generate a normalization factor. During the scanning of a portion, a previously scanned portion may be played. This embodiment may also be referred to as a one pass method.

In another embodiment, the loudness adjustment to the audio signal may be a volume normalization of all of the music tracks corresponding to a music selection. In other words, reproducing the audio signal, or playing multiple musical tracks, can have the same volume level entirely throughout all the tracks of a music selection. In such an embodiment, the entire music track is scanned to generate a normalization factor for the entire music track. After this step, the music track may be played. This embodiment may also be referred to as a two pass method.

After the loudness level of the audio signal has been adjusted, the audio signal is inputted to the audio compression module 208. At the audio compression module 208, the audio signal is compressed and modified to implement the appropriate gain level for achieving the desired loudness level. The audio compression module 208 may include a Digital Signal Processor (DSP) module. The DSP module includes any processor that is capable of processing a signal and providing computations.

In still another embodiment, the invention provides a method for compiling an audio play list with similar loudness levels. In this embodiment, a first music selection is selected from multiple audio sources. Next, a perceptual loudness level of an audio signal is measured corresponding to the first music selection. Thereafter, the contents of a music selection list are searched for a second music selection using the measured perceptual loudness level of the first music selection. As a result, a second music selection is inserted into an audio play list. Preferably, the second music selection has a perceptual loudness level that is similar to the measured perceptual loudness level of the first music selection.

In some instances the aforementioned steps could be performed in an order other than that specified above. The description is not intended to be limiting with respect to the order of the steps.

In another embodiment, an additional step for compiling an audio play list may include identifying a second music selection if the second music selection has a perceptual loudness level that is similar to the measured perceptual loudness of the first music selection. In an alternate embodiment, an additional step for compiling an audio play list may include rejecting the second music selection if the second music selection has a perceptual loudness level that is not similar to the measured perceptual loudness of the first music selection; and detecting the energy level corresponding to the music selection. Using the preferred loudness model, and typical values for input, the calculated loudness ranges from 0 to 2500 in arbitrary units. The amount of similarity may depend on the overall loudness, the listeners' preferences, and other considerations such as time of day, the type of listening device such as a headphone or speaker, or other variables.

The invention is described in the general context of computer-executable instructions, such as program modules, being executed by a computer. Generally, program modules include routines, programs, objects, components, data structures, etc. that perform particular tasks or implement particular abstract data types. Moreover, those skilled in the art will appreciate that the invention may be practiced with other computer system configurations, including hand-held devices, multiprocessor systems, microcontroller-based, microprocessor-based, or programmable consumer electronics, minicomputers, mainframe computers, and the like. The invention may also be practiced in distributed computing environments where tasks are performed by remote processing devices that are linked through a communications network. In a distributed computing environment, program modules may be located in both local and remote computer storage media including memory storage devices.

The invention claimed is:

1. A method for equalizing the loudness of an audio source, comprising:
measuring the perceptual loudness level of one or more portions of an audio signal;
adjusting the perceptual loudness level of the one or more portions of the audio signal; and
reproducing the one or more portions of the audio signal at the adjusted loudness level to a listener.

2. The method of claim 1, wherein adjusting the perceptual loudness level comprises: selecting a target loudness for each portion one or more portions; and adjusting each portion of the one or more portions to the target level.

3. The method of claim 2, wherein measuring the perceptual loudness level further comprises: assigning the target loudness to each portion of the one or more portions.

4. The method of claim 1, wherein adjusting the perceptual loudness level further comprises: normalizing each portion by a normalization factor to reach the target loudness, wherein the normalization factor is determined based on a peak loudness corresponding to each portion of the one or more portions.

5. The method of claim 1, wherein measuring the perceptual loudness level further comprises: generating a frequency domain representation of the one or more portions of the audio signal.

6. The method of claim 5, wherein measuring the perceptual loudness level further comprises: mapping the frequency domain to a model of the cochlear domain.

7. The method of claim 6, wherein measuring the perceptual loudness level further comprises: calculating the partial perceptual loudness values corresponding to the audio signal.

8. The method of claim 7, wherein measuring the perceptual loudness level further comprises: aggregating the partial perceptual loudness values corresponding to the audio signal.

9. The method of claim 8, wherein measuring the perceptual loudness level further comprises: comparing the aggregated partial perceptual loudness values to the target loudness level.

10. The method of claim 9, wherein adjusting the loudness level further comprises: determining the appropriate gain level using the comparison results of the aggregated partial perceptual loudness values with the target loudness level for inputting the one or more portions of the audio signal into an audio compressor.

11. The method of claim 1, wherein adjusting the loudness level further comprises: normalizing the loudness of the music track by a normalization factor to reach the target loudness.

12. The method of claim 11, wherein the normalization factor is determined based on a maximum loudness corresponding to the music track.

13. A method for compiling an audio play list with similar loudness levels, comprising:
measuring the perceptual loudness level of an audio signal corresponding to a first music selection;
identifying a second music selection having the measured perceptual loudness level of the first music selection; and
inserting a second music selection to an audio play list, the second music selection having a perceptual loudness level that is similar to the measured perceptual loudness level of the first music selection.

14. The method of claim 13, further comprising: identifying a second music selection if the second music selection has a perceptual loudness level that is similar to the measured perceptual loudness of the first music selection.

15. The method of claim 14, wherein measuring the perceptual loudness level further comprises: detecting the energy level corresponding to the music selection.
